(19) United States
(12) Patent Application Publication
(10) Pub. No.: US 2002/0074647 A1
(43) Pub. Date: Jun. 20, 2002

(54) Device for a clocked semiconductor chip

(76) Inventors: Jurgen Wolf, Villingen-Schwenningen (DE); Hubert Grunebaum, Niedereschach (DE)

Correspondence Address: Martin A. Farber, Suite 473, 866 United Nations Plaza, New York, NY, 10017, US

(21) Appl. No.: 09/988,497

(22) Filed: Nov. 19, 2001

(30) Foreign Application Priority Data
Nov. 22, 2000 (DE) 100 57 973.6

(51) Int. Cl. H01L 23/34

(52) U.S. Cl. 257/712

(57) ABSTRACT

For a device for a clocked semiconductor chip, the semiconductor chip (1) being mounted on a support (2) provided with electrical conductor tracks, it is proposed to arrange a shielding body (3), consisting of a heat-conducting material and covering the semiconductor chip (1) at least partly, between the surface of the semiconductor chip (1) and a cooling element (4) belonging to the semiconductor chip (1),

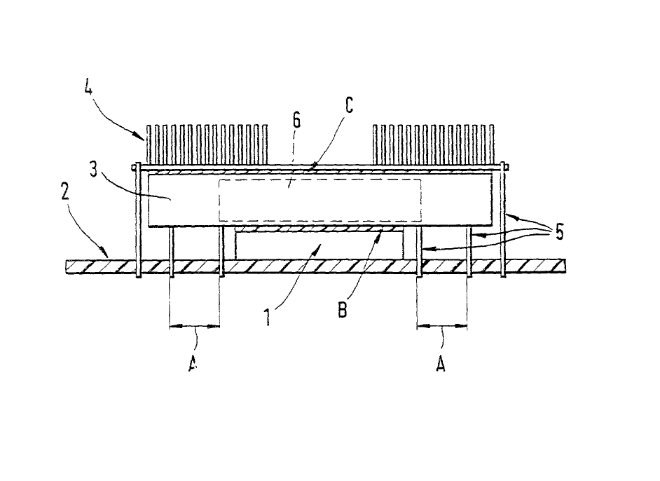

the shielding body (3) being in heat-conducting connection both with the semiconductor chip (1) and with the cooling element (4) and

the shielding body (3) containing ferrite, in order to absorb electromagnetic interference signals which the semiconductor chip (1) emits on account of its clock frequency.

The invention relates to a device for a clocked semiconductor chip, in particular for a microprocessor or microcontroller. Clocked semiconductor chips are driven with ever higher clock frequencies to achieve ever higher operating speeds. Clock frequencies of this type are nowadays already in the range of several hundred megahertz and consequently in the radio-frequency range, which is used by a variety of electronic communication devices for wireless information transmission. The operation of a semiconductor chip clocked with a high clock frequency is consequently accompanied by two problems, that is that the semiconductor chip intensely heats up due to its high clock timing and that it produces electromagnetic interference signals for other electronic devices, in particular by emitting high-frequency harmonics.

Specifically where such semiconductor chips are used in automotive applications, the interference signals emitted from them lead to other control devices being influenced, sometimes dangerously, or at least to an impairment in the quality of communication devices arranged in a vehicle, such as a radio or telephone. In the worst case, the influencing or impairment may lead to a total functional failure of said control devices or communication devices, for which reason a high interference level resulting from a semiconductor chip cannot be tolerated in a vehicle. Although it is known to equip control devices or communication devices with suitable protective elements such as filters etc., in order to minimize an adverse influence caused by signals radiated in from their surroundings, it is more meaningful to eliminate electromagnetic interference signals at their source or at least to lessen or limit their effect to a considerable extent at their source.

For heat dissipation, forced cooling is therefore generally provided, and may be designed in such a way

that a heat sink is provided on the semiconductor chip to increase its heat-dissipating surface area,

that a fan or an air duct is provided, which generates or provides an air stream flowing over the semiconductor chip for transporting away the heat given off by the semiconductor chip, or

that the semiconductor chip is brought into operative connection with a series of electrical conductors, in order to create a heat pump by utilizing the Peltier effect.

These measures may be used alone or in combination. It should be noted in this respect

that active forced-cooling means provided by a generated air stream or by a Peltier element require for their part an electronic controller and are consequently relatively complex to realize,

that they inevitably increase the energy consumption of the structural unit in which they are arranged, which is undesired, however, specifically in a vehicle,

that under some circumstances they may themselves have to be monitored and

that in the overall “vehicle” system they represent an additional source of faults, because even they are not completely immune to an operational malfunction.

For shielding from electromagnetic interference signals, usually high-frequency-absorbing sheets of an iron or aluminum material are used or coatings consisting of a corresponding material are applied in the inner region of the housing surrounding the semiconductor chip, these forms of a shielding having to be arranged at some distance from the semiconductor chip in order to avoid a reduction in their shielding effect. As a result, however, arrangements of this type require a relatively large overall volume, which in vehicles in particular can be provided only with difficulty.

It is consequently the object of the present invention to present a device for a clocked semiconductor chip which, while requiring little space, acts in a heat-dissipating manner and at the same time absorbs high-frequency electromagnetic radiation.

The object is achieved by a device for a clocked semiconductor chip having the features of the first claim. The solution achieving this provides in particular

that a shielding body, consisting of a heat-conducting material and covering the semiconductor chip at least partly, is arranged between the surface of the semiconductor chip and a cooling element belonging to the semiconductor chip,

that the shielding body is in heat-conducting connection both with the semiconductor chip and with the cooling element and

that the shielding body contains ferrite, in order to absorb electromagnetic interference signals which the semiconductor chip emits on account of its clock frequency.

Further advantageous refinements and developments of the solution found also emerge in conjunction with the attached FIGURE, with the aid of which this solution is now to be illustrated further.

A clocked semiconductor chip 1 is mounted on a support 2 provided with electrical conductor tracks, the support 2 generally being designed in the form of a printed-circuit board. A shielding body 3, preferably of a flat form, covers the semiconductor chip 1 mounted on the support 2 at least partly, to be specific at least in those spatial directions in which a shielding effect against electromagnetic interference signals is intended. In this case, the shielding body 3 may have, for example, a layer thickness of 2 millimeters. The shielding body 3 consists of a heat-conducting material and is in heat-conducting connection both with the semiconductor chip 1 and with a cooling element 4, i.e. it is intended for there to be a heat transfer that is as unhindered as possible at the respective contact points B and C of the semiconductor chip 1, shielding body 3 and cooling element 4, shown spaced apart in the FIGURE for technical-drawing reasons. This heat-conducting connection may be realized by a form-fitting design of the contact surfaces of the semiconductor chip 1, shielding body 3 and cooling element 4 in conjunction with a clamping of the shielding body 3 between the semiconductor chip 1 and the cooling element 4. To improve the heat transfer from the semiconductor chip 1 to the shielding body 3 and from the shielding body 3 to the cooling element 4 still further, these heat transfer points B and C are preferably provided with a heat-conducting paste, a heat-conducting adhesive or a heat-conducting foil. The cooling element 4 may be designed in an accustomed way as a heat sink in rib form or as a honeycombed perforated sheet. If the heat sink consists of aluminum, it is recommendable for it to be anodized. The shielding body 3 and the cooling element 4 may also be fastened to the support 2 by pins 5, the pins 5 preferably being set at regular intervals and a suitable spacing A for the pins 5 being determined by taking the frequency to be attenuated into account. With a frequency to be shielded of, for example, f=400 MHz, a spacing A of approximately 30 millimeters is recommendable. The pins 5 are preferably plated-through to the support 2 and grounded there. Ferrite is advantageous as the material for the shielding body 3 because of its radiation-absorbing effect. The shielding body 3 may either be produced completely from ferrite or have a flat core 6 of ferrite covering the semiconductor chip 1. If it is not necessary for the shielding body 3 or its core 6 consisting of ferrite to cover the semiconductor chip 1 completely, other geometries adapted to the radiation behavior of the semiconductor chip 1 are also possible of course for the shielding body 3, and may range from partial coverings to shroud-shaped surrounds of the semiconductor chip 1, according to requirements. Similarly, to increase the absorption of electromagnetic interference signals, powdered ferrite materials can also be introduced into a paste as a substitute for a heat-conducting paste, a heat-conducting adhesive or a heat-conducting foil that is used, or else the heat-conducting paste, the heat-conducting adhesive or the heat-conducting foil are made to contain powdered ferrite materials themselves. In a further refinement of the invention, the shielding body 3 and the cooling element 4 may also be compressed to form a one-piece component, or heat-dissipating surfaces or ribs, forming a heat sink, are formed directly onto the shielding body 3.

The proposed arrangement of the shielding body 3 and cooling element 4 achieve the effect of producing a device for a clocked semiconductor chip 1 which, while requiring little space, acts in a heat-dissipating manner and at the same time absorbs high-frequency electromagnetic radiation. In this way, extremely flat structural forms can be achieved, which are also suitable for microcontrollers for activating instrument clusters in vehicles.

1. Device for a clocked semiconductor chip,
1.1. the semiconductor chip (1) being mounted on a support (2) provided with electrical conductor tracks, characterized
1.2. in that a shielding body (3), consisting of a heat-conducting material and covering the semiconductor chip (1) at least partly, is arranged between the surface of the semiconductor chip (1) and a cooling element (4) belonging to the semiconductor chip (1),
1.3. in that the shielding body (3) is in heat-conducting connection both with the semiconductor chip (1) and with the cooling element (4) and
1.4. in that the shielding body (3) contains ferrite, in order to absorb electromagnetic interference signals which the semiconductor chip (1) emits on account of its clock frequency.

2. Device for a clocked semiconductor chip according to claim 1, characterized in that the shielding body (3) is of a flat form.

3. Device for a clocked semiconductor chip according to one of the preceding claims, characterized in that the shielding body (3) is produced completely from ferrite or has a core (6) of ferrite covering the semiconductor chip (1) at least partly.

4. Device for a clocked semiconductor chip according to one of the preceding claims, characterized in that the shielding body (3) is clamped between the surface of the semiconductor chip (1) and the cooling element (4) belonging to the semiconductor chip (1).

5. Device for a clocked semiconductor chip according to one of the preceding claims, characterized in that the heat transfer points between the semiconductor chip (1) and the shielding body (3) or between the shielding body (3) and the cooling element (4) belonging to the semiconductor chip (1) are provided with a heat-conducting paste, a heat-conducting adhesive or a heat-conducting foil.

6. Device for a clocked semiconductor chip according to claim 5, characterized in that the heat-conducting paste, the heat-conducting adhesive or the heat-conducting foil contain powdered ferrite materials.

7. Device for a clocked semiconductor chip according to one of the preceding claims, characterized in that the cooling element (4) is designed as a heat sink in rib form or as a honeycombed perforated sheet.

8. Device for a clocked semiconductor chip according to one of the preceding claims, characterized in that the shielding body (3) or the cooling element (4) are fastened to the support (2) by pins (5), the pins (5) being set at regular intervals and a suitable spacing for the pins (5) being determined by taking the frequency to be attenuated into account.

9. Device for a clocked semiconductor chip according to claim 8, characterized in that the pins (5) are grounded on the support (2).

10. Device for a clocked semiconductor chip according to one of the preceding claims, characterized in that the shielding body (3) and the cooling element (4) are compressed to form a one-piece component.

11. Device for a clocked semiconductor chip according to one of the preceding claims, characterized in that heat-dissipating surfaces or ribs are formed onto the shielding body (3).
